(19) United States
(12) Patent Application Publication
(10) Pub. No.: US 2013/0108890 A1
(43) Pub. Date: May 2, 2013

(54) Target, An Underlayer Material For Co-Based Or Fe-Based Magnetic Recording Media, And Magnetic Recording Media

(71) Applicants: Shang-Hsien Rou, Tainan (TW); Tien-Chieh Wu, Tainan (TW); Shang-Chieh Hou, Tainan (TW); Yung-Chun Hseuh, Tainan (TW)

(72) Inventors: Shang-Hsien Rou, Tainan (TW); Tien-Chieh Wu, Tainan (TW); Shang-Chieh Hou, Tainan (TW); Yung-Chun Hseuh, Tainan (TW)

(73) Assignee: Solar Applied Materials Technology Corp, Tainan (TW)

(21) Appl. No.: 13/283,662

(22) Filed: Oct. 28, 2011

(51) Int. Cl. G11B 5/66; C23C 14/08; G11B 5/706; C23C 14/34

(52) U.S. Cl. 428/832.1; 204/298.13; 428/846.1; 428/832

(57) ABSTRACT

The present invention is related to a target, which is a magnesium monoxide-based (MgO-based) composite having cubic crystal structure of MgO, wherein the MgO-based composite includes MgO and one or more oxides. Using MgO-based composite to form an underlayer material can improve the bonding strength among particles in the target, and then effectively reduce the falling of particles from the targets during sputtering. In addition, the MgO-based composite still maintains the cubic crystal structure of MgO, which is beneficial to make a MgO-based composites as an underlayer material in a magnetic recording medium. The invention is also related to an underlayer material for cobalt-based (Co-based) or iron-based (Fe-based) magnetic recording media. The invention is further related to a magnetic recording medium.

### BACKGROUND OF THE INVENTION

1. Field of the Invention

The invention is related to a target, specifically related to a target that can improve bonding strength among particles and is used as underlayer materials for Co-based or Fe-based magnetic recording media.

2. Description of the Prior Arts

CoCr-based composite is usually used in recording layers of perpendicular magnetic recording media. Generally, in order to make the disposed film of recording layer have uniformly distributed grains, desired roughness and proper orientation of grain growth, underlayers below the recording layers are usually made from ruthenium-based and platinum materials, such as ruthenium-oxides (Ru-oxide) and ruthenium alloy (Ru—X, X represents metal element).

Many researches correlated to iron-based (Fe-based) or cobalt-based (Co-based) recording layers with high magnetic anisotropy have been reported. Conventionally, those magnetically anisotropic recording layers are beneficial to increase magnetic recording density. The underlayer materials are mostly made from magnesium monoxide (MgO), which has cubic crystal structure, in order to allow the recording layer material to have proper orientation of grain growth and the particles to distribute separately without mutual affection. However, targets made from only magnesium monoxide could lead to the falling of particles and then forming of defects in the disposed film of underlayers during sputtering. The defects in the film decrease the yield rate of production. Therefore, to overcome the shortcomings of conventional underlayer materials for Co-based and/or Fe-based magnetic recording media, the present invention provides a target to mitigate or obviate the aforementioned problems.

### SUMMARY OF THE INVENTION

The primary objective of the present invention provides a target that is used as underlayer materials for Co-based or Fe-based magnetic recording media and can improve bonding strength among particles. The target in accordance with the present invention can overcome the falling of particles and formation of defects in the disposed film of the underlayers during sputtering.

To achieve the objective, the target in accordance with the present invention is an MgO-based composite having cubic crystal structure of MgO, wherein the MgO-based composite comprises MgO and one or more oxides.

Preferably, the one or more oxides comprise substance(s) selected from a group consisting of zinc monoxide (ZnO), nickel monoxide (NiO), iron monoxide (FeO) and a combination thereof.

The secondary objective of the present invention provides an underlayer material for Co-based or Fe-based magnetic recording media, wherein the underlayer is an MgO-based composite made from sputtering the said target, and the MgO-based composite substantially consists of MgO, one or more oxides, and other unavoidable impurities.

Preferably, the one or more oxides comprise substance(s) selected from a group consisting of zinc monoxide (ZnO), nickel monoxide (NiO), iron monoxide (FeO) and a combination thereof.

The tertiary objective of the present invention provides a magnetic recording medium, which comprises an underlayer and a cobalt-based or iron-based magnetic recording layer disposed on the underlayer, wherein the underlayer is an MgO-based composite made from sputtering the said target, and the MgO-based composite substantially consists of MgO, one or more oxides, and other unavoidable impurities.

Preferably, the one or more oxides comprise substance(s) selected from a group consisting of zinc monoxide (ZnO), nickel monoxide (NiO), iron monoxide (FeO) and a combination thereof.

In accordance with the present invention, “substantially consists of” means a material mainly comprises the specified substance, whereas the material also includes other unavoidable impurities. Specifically, the MgO-based composite mainly consists of MgO and one or more oxides, wherein the MgO-based composite contains other unavoidable impurities.

Using the targets composed of MgO-based composite in accordance with the present invention to form an underlayer material can improve the bonding strength among particles, and reduce the falling of particles effectively. The lattice constant of each of the one or more oxides is smaller than that of MgO, and the one or more oxides can form single solid solution phase with MgO. Accordingly, adding the one or more oxides into the MgO-based composite can maintain the original cubic crystal structure of MgO, and thus maintain properties and functions of the underlayer materials.

Other objectives, advantages and novel features of the invention will become more apparent from the following detailed description when taken in conjunction with the accompanying drawings.

### BRIEF DESCRIPTION OF THE DRAWINGS

FIG. 1 is a metallographic microscope image of a conventional MgO-based target in comparative example 1 in accordance with the prior art.

FIG. 2 is an x-ray diffraction image of a conventional MgO target in comparative example 1 in accordance with the prior art.

FIG. 3 is a metallographic microscope image of an MgO—NiO target in example 1 in accordance with the present invention.

FIG. 4 is an x-ray diffraction image of an MgO—NiO target in example 1 in accordance with the present invention.

FIG. 5 is a metallographic microscope image of an MgO—ZnO target in example 2 in accordance with the present invention.

FIG. 6 is an x-ray diffraction image of an MgO—ZnO target in example 2 in accordance with the present invention.

### DETAILED DESCRIPTION OF THE PREFERRED EMBODIMENTS

The present invention provides a target, which is an underlayer material for forming cobalt-based or iron-based magnetic recording medium. Wherein, the target is an MgO-based composite having cubic crystal structure of MgO, wherein the MgO-based composite comprises MgO, one or more oxides, and other unavoidable impurities.

In a preferred embodiment, the one or more oxides comprise substance(s) selected from a group consisting of zinc monoxide (ZnO), nickel monoxide (NiO), iron monoxide (FeO) and a combination thereof.

The present invention also provides an underlayer material for Co-based or Fe-based magnetic recording media, wherein the underlayer material is a MgO-based composite, and the MgO-based composite substantially consists of MgO and one or more oxides.

In a preferred embodiment, the one or more oxides comprise substance(s) selected from a group consisting of zinc monoxide, nickel monoxide, iron monoxide and a combination thereof.

The present invention provides a magnetic recording medium, which comprises an underlayer and a cobalt-based or iron-based recording layer disposed on the underlayer, wherein the underlayer is a MgO-based composite, and the MgO-based composite substantially consists of MgO and one or more oxides.

In a preferred embodiment, the one or more oxides comprise substance(s) selected from a group consisting of zinc monoxide, nickel monoxide, iron monoxide and a combination thereof.

The present invention is further illustrated by the following examples; it should be understood that the examples and embodiments described herein are for illustrative purposes only and should not be construed as limiting the embodiments set forth herein.

### EXAMPLES

### Comparative Example 1

### Producing an MgO Target

400 grams of MgO powder (average particle size: 1 μm) were baked at 450° C. for 120 minutes. Then, the powder was filled and well distributed into a graphite mold, then compacted to form a green compact under a hydraulic press of 300 psi. The graphite mold with the green compact was put into a hot-pressing furnace and the green compact was sintered at 1300° C. under 381 bar for 240 minutes to obtain an MgO target.

Then, after putting three pieces of the MgO sample target respectively on the first, second and third rotating plates, each sample piece is tested by RF sputtering at room temperature at 150 watt (W) for 1035 seconds. A particle counter (KLA Tencor 6420) counts the number of particles falling from the pieces of the MgO sample target during sputtering and the result is shown in Table 1 as described below.

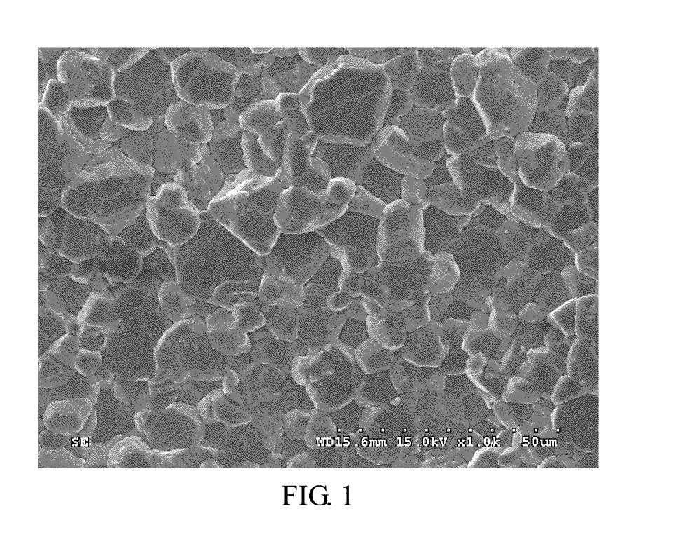

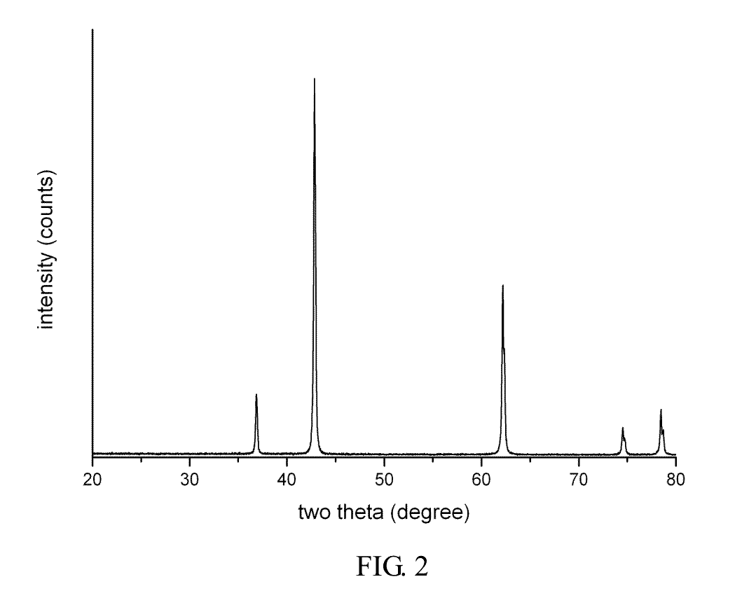

FIG. 1 shows a metallographic microscope image of the MgO target of the comparative example 1 taken by scanning electron microscope (Hitachi N-3400 SEM), and FIG. 2 shows an X-ray powder diffraction image of the MgO target of the comparative example 1 taken by X-ray diffractometer (Bruker-AXS Siemens). The absolute density of the MgO target measured by Archimedes method divided by theoretical density equals the relative density thereof.

As shown in FIG. 1, the MgO target has a dense structure with an average grain size ranging from 5 μm to 25 μm. As shown in FIG. 2, the structure of the MgO target is similar to that of periclase; that is, the MgO target has a cubic crystal structure. The relative density of the MgO target is greater than 98.5% by calculation. As shown in Table 1, the average number of particles falling from the three pieces of the MgO sample target during sputtering is 83 per square inch.

### Example 1

### Producing a 60MgO-40NiO Target

175.02 grams of MgO powder (average particle size: 1 μm), 216.23 grams of NiO powder (average particle size: 1.5 μm) were mixed by roller powder-mixing machine for 120 minutes following that MgO powder had been baked at 450° C. for 120 minutes. Then, those powders were sieved with a 60-mesh sieve. The powders sieved with the 60-mesh sieve were mixed homogeneously to form a mixture. The mixture is filled and well distributed into a graphite mold, then compacted to form a green compact under a hydraulic press of 300 psi. The graphite mold with the green compact was put into a hot-pressing furnace and the green compact was sintered at 1300° C. under 381 bar for 240 minutes to obtain a 60MgO-40NiO target (hereinafter “MgO—NiO target”).

Then, after putting three pieces of the MgO—NiO sample target respectively on the first, second and third rotating plates, each sample piece is tested by RF sputtering at room temperature at 150 W for 1035 seconds. A particle counter (KLA Tencor 6420) counts the number of particles falling from the pieces of the MgO—NiO sample target during sputtering and the result is shown in Table 1 as described below.

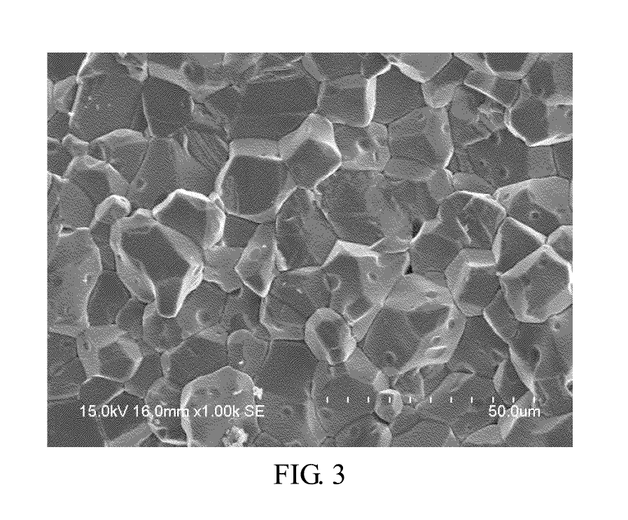

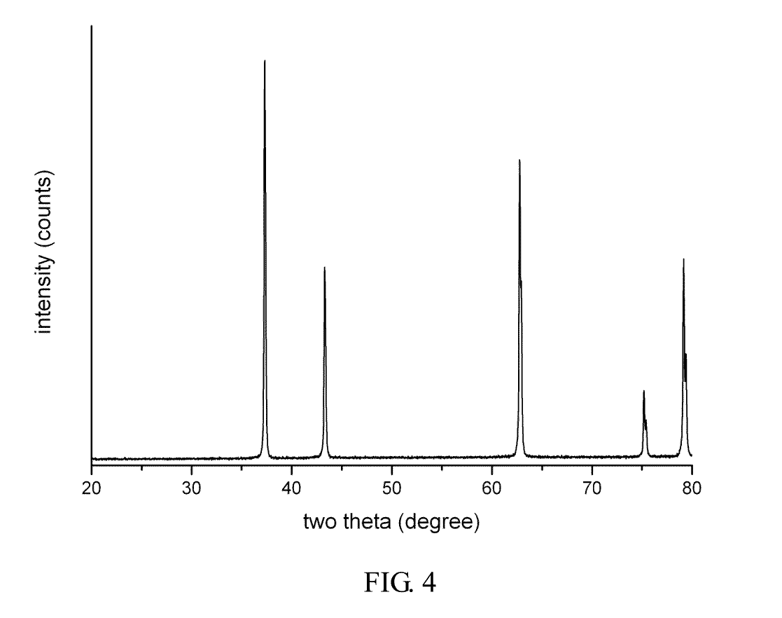

FIG. 3 shows a metallographic microscope image of the MgO—NiO target of the example 1 taken by scanning electron microscope (Hitachi N-3400 SEM), and FIG. 4 shows an X-ray powder diffraction image of the MgO—NiO target of the example 1 taken by X-ray powder diffractometer (Bruker-AXS Siemens). The crystalline structure of the MgO—NiO target is also compared with the database of Joint Committee on Powder Diffraction Standards (JCPDS). The absolute density of the MgO—NiO target measured by Archimedes method divided by theoretical density equals the relative density thereof.

TABLE 1
Comparison of the numbers of particles falling from the
MgO target, the 60MgO—40NiO target and the 90MgO—10ZnO
target and the decreasing percentages of particles

| | | 60MgO—40NiO | 90MgO—10ZnO |
|---|---|---|---|
| | MgO target | target | target |
| | (Number of | (Number of | (Number of |
| | particles/inch²) | particles/inch²) | particles/inch²) |
| First rotating | 83 | 51 | 67 |
| plate | | | |
| Second rotating | 88 | 55 | 65 |
| plate | | | |
| Third rotating | 77 | 57 | 71 |
| plate | | | |
| Average number | 83 | 54 | 68 |
| of particles | | | |
| Decreasing | n/a | About 35% | About 18% |
| percentage | | | |
| of particles | | | |

As shown in FIG. 3, the MgO—NiO target has a dense structure with an average grain size ranging from 5 μm to 25 μm. As shown in FIG. 4, the structure of the MgO—NiO target is similar to that of periclase; that is, the MgO—NiO target also has a cubic crystal structure. The relative density of the MgO—NiO target is greater than 98.5% by calculation. As shown in Table 1, the average number of particles falling from the MgO—NiO target of the three sample pieces during sputtering is 54 per square inch. Compared with the MgO target in accordance with the comparative example 1, the particles falling from the MgO—NiO target are about 35% less than those falling from the MgO target (i.e. the percentage is calculated by dividing the difference between the numbers of particles falling from MgO target and MgO—NiO target by the number of particles falling from MgO target, wherein the difference between the numbers of particles falling from two targets is that the number of particles falling from the MgO target minus the number of particles falling from the MgO—NiO target.

### Example 2

### Producing a 90MgO-10ZnO Target

332 grams of MgO powder (average particle size: 1 μm), 74.4 grams of ZnO powder (average particle size: 0.5 μm) were mixed by roller powder-mixing machine for 120 minutes following that MgO powder had been baked at 450° C. for 120 minutes. Then, those powders were sieved with a 60-mesh sieve. The powders sieved with the 60-mesh sieve were mixed homogeneously to form a mixture. The mixture is filled and well distributed into a graphite mold, then compacted to form a green compact under a hydraulic press of 300 psi. The graphite mold with the green compact was put into a hot-pressing furnace and the green compact was sintered at 1300° C. under 381 bar for 240 minutes to obtain a 90MgO-10ZnO target (hereinafter “MgO—ZnO target”).

Then, after putting three pieces of the sample MgO—ZnO target respectively on the first, second and third rotating plates, each sample piece is tested by sputtering at room temperature under 150 W for 1035 seconds. A particle counter (KLA Tencor 6420) counts the number of particles falling from the pieces of the sample MgO—ZnO target during sputtering and the result is shown in Table 1.

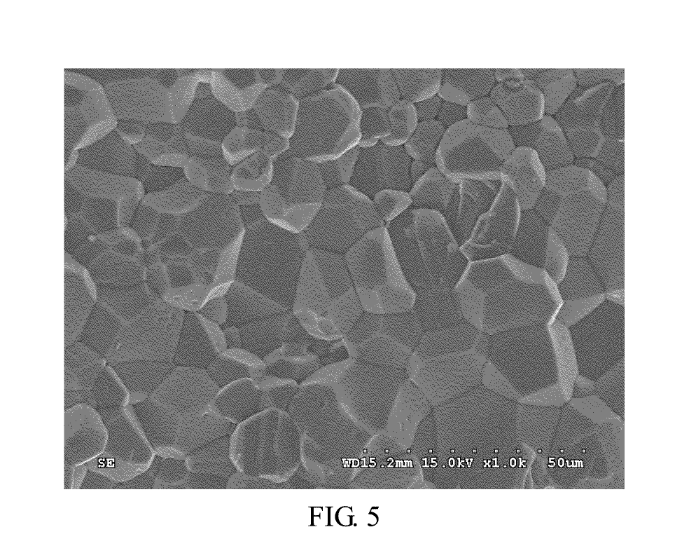

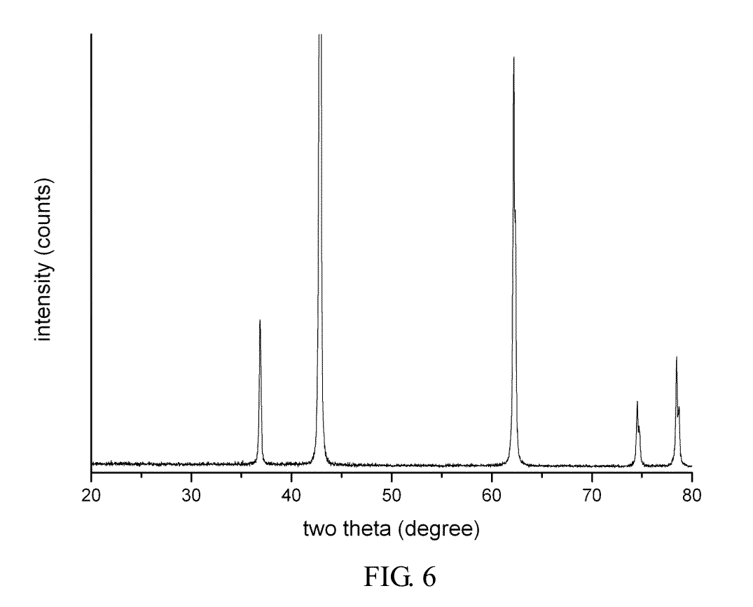

FIG. 5 shows a metallographic microscope image of the MgO—ZnO target of the example 2 taken by scanning electron microscope (Hitachi N-3400 SEM), and FIG. 6 shows an X-ray powder diffraction image of the MgO—ZnO target of the example 2 taken by X-ray powder diffractometer (Bruker-AXS Siemens). The crystalline structure of the MgO—ZnO target is also compared with the database of Joint Committee on Powder Diffraction Standards (JCPDS). The absolute density of the MgO—ZnO target measured by Archimedes method divided by theoretical density equals the relative density thereof.

As shown in FIG. 5, the MgO—ZnO target has a dense structure with an average grain size ranging from 5 μm to 25 μm. As shown in FIG. 5, the structure of the MgO—ZnO target is similar to that of periclase; that is, the MgO—ZnO target also has a cubic crystal structure. The relative density of the MgO—ZnO target is greater than 98.5% by calculation. As shown in Table 1, the average number of particles falling from the MgO—ZnO target of the three sample pieces during sputtering is 68 per square inch. Compared with the MgO target in accordance with the comparative example 1, the particles falling from the MgO—ZnO target are about 18% less than those falling from the MgO target (i.e. the percentage is calculated by dividing the difference between the numbers of particles falling from MgO target and MgO—ZnO target by the number of particles falling from MgO target.

Based on the description mentioned above, the present invention provides a target made from a composite having MgO and other metal oxides, which can be used as underlayer materials of Co-based or Fe-based magnetic recording media. The average number of the particles falling from the target in accordance with the present invention is greatly decreased during sputtering. Additionally, the cubic crystal structure of the target can be stable and is beneficial to application in manufacturing underlayer materials of Co-based or Fe-based magnetic recording media.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

1. A target, which is used for sputtering an underlayer material of Co-based or Fe-based magnetic recording media, wherein the target consists of an MgO-based composite having cubic crystal structure of MgO, the MgO-based composite comprises MgO and one or more oxides differentiated from MgO, and the target has a relative density greater than 98.5%.

2. The target as claimed in claim 1, wherein the one or more oxides comprise substance(s) selected from a group consisting of zinc monoxide, nickel monoxide, iron monoxide and a combination thereof.

3. An underlayer material for Co-based or Fe-based magnetic recording media, which is an MgO-based composite made from sputtering the target as claimed in claim 1, wherein the MgO-based composite comprises MgO and one or more oxides differentiated from MgO.

4. The underlayer material for Co-based or Fe-based magnetic recording media as claimed in claim 3, wherein the one or more oxides comprise substance(s) selected from a group consisting of zinc monoxide, nickel monoxide, iron monoxide and a combination thereof.

5. A magnetic recording medium, which comprises an underlayer and a Co-based or Fe-based magnetic recording layer disposed on the underlayer, wherein the underlayer material is an MgO-based composite made from sputtering the target as claimed in claim 1, and the MgO-based composite comprises MgO and one or more oxides differentiated from MgO.
